(19) United States
(12) Patent Application Publication
(10) Pub. No.: US 2026/0157093 A1
(43) Pub. Date: Jun. 4, 2026

(54) TRANSPARENT DISPLAY APPARATUS

(71) Applicant: LG Display Co., Ltd., Seoul (KR)

(72) Inventors: DongYoon KIM, Paju-si (KR); Dahye KWON, Paju-si (KR); Taehee KO, Paju-si (KR)

(73) Assignee: LG Display Co., Ltd., Seoul (KR)

(21) Appl. No.: 19/280,009

(22) Filed: Jul. 24, 2025

(30) Foreign Application Priority Data
Dec. 3, 2024 (KR) 10-2024-0178003

(51) Int. Cl. H10K 59/80; H10K 59/122

(52) U.S. Cl. CPC H10K 59/8791; H10K 59/122

(57) ABSTRACT

A transparent display apparatus according to one embodiment of the present disclosure comprises a substrate including a display area, which includes a transmissive area and a non-transmissive area adjacent to the transmissive area. A plurality of subpixels is arranged in the non-transmissive area. A plurality of inorganic films is provided in the non-transmissive area and forms a step due to process variation. A planarization layer covers the plurality of inorganic films and partially includes a light path changing portion. The light path changing portion is configured to change the path of light incident on or passing through the transmissive area, thereby reducing diffraction caused by the step and improving clarity of objects or images viewed through the transmissive area. This structure may enhance optical performance in transparent regions while maintaining uniformity and efficiency in light emission across the display area.

### CROSS-REFERENCE TO RELATED APPLICATIONS

This application claims the benefit of the Republic of Korea Patent Application No. 10-2024-0178003 filed on Dec. 3, 2024, which is hereby incorporated by reference in its entirety.

### BACKGROUND

### Technical Field

The present disclosure relates to a transparent display apparatus.

### Description of the Related Art

With the advancement of the information age, the demand for a display apparatus for displaying an image has increased in various forms. Therefore, various types of display apparatuses such as a liquid crystal display (LCD) apparatus, a plasma display panel (PDP) apparatus, an organic light emitting display (OLED) apparatus and a quantum dot light emitting display (QLED) apparatus have been used.

Recently, studies for a transparent display apparatus in which a user may view objects or images positioned at an opposing side by transmitting the display apparatus are actively ongoing.

The transparent display apparatus may include a display area, on which an image is displayed, in a substrate, and the display area may include a transmissive area capable of transmitting external light and a non-transmissive area that does not transmit light.

### BRIEF SUMMARY

In the related art, a plurality of inorganic films may be arranged adjacent to the transmissive area of the transparent display apparatus, and these inorganic films may form a step due to process margins. However, the inventors of the present disclosure have recognized that such a step adjacent to the transmissive area can degrade the clarity of objects or images viewed through it, as light passing through the transmissive area may be diffracted by the step.

Various embodiments of the present disclosure is to provide a transparent display apparatus capable of improving a clarity of an object or an image shown to a user through a transmissive area.

Various embodiments of the present disclosure provide a transparent display apparatus in which a light efficiency of a light emission area (or a display area) can be improved.

Various embodiments of the present disclosure provide a transparent display apparatus in which the overall power consumption may be reduced.

Various embodiments of the present disclosure provide a transparent display apparatus in which dark spot defects can be improved.

The technical benefits of the present disclosure are not limited to the above-mentioned benefits, and other benefits, which are not mentioned above, can be clearly understood by those skilled in the art from the following descriptions.

For instance, the transparent display apparatus enhances clarity in transmissive areas by using a planarization layer that includes a light path changing portion-such as patterned or roughened surfaces—that redirects incident light to reduce diffraction caused by steps in nearby inorganic layers. To maintain high reflectivity in light-emitting regions, the pixel electrodes are formed before the ashing process, ensuring a flat surface under the emissive stack. The use of fluorine-doped transparent electrodes (FTO) in red and blue subpixels further improves light transmittance and boosts overall light extraction efficiency.

Additional efficiency is achieved by optimizing microcavity resonance through multi-layered pixel electrodes with tailored thicknesses and specific material choices, such as ITO/Ag/ITO, FTO, and IZO. The subpixel layout adopts a pinwheel configuration, where a white subpixel extends into the transmissive region, reducing the need for a black matrix and allowing greater transparency. This combination of structural and material improvements contributes to higher display efficiency and reduced power consumption.

An example transparent display apparatus according to one embodiment of the present disclosure comprises a substrate including a display area, each of which is provided with a transmissive area and a non-transmissive area adjacent to the transmissive area and having a plurality of subpixels arranged therein; a plurality of inorganic films provided in the non-transmissive area and having a step; and a planarization layer covering the plurality of inorganic films, wherein the planarization layer partially includes an light path changing portion.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a transparent display apparatus according to one embodiment of the present disclosure.

FIG. 2 is a schematic enlargement of portion A of FIG. 1, showing a single pixel.

FIG. 3 is a schematic cross-sectional view of the line I-I′ shown in FIG. 2.

FIG. 4 is a cross-sectional view showing one example of a pixel electrode illustrated in FIG. 3.

FIG. 5 is a schematic graph showing the transmittance according to wavelength of a transparent display apparatus according to one embodiment of the present disclosure.

FIG. 6 is a schematic cross-sectional view of the line II-II′ shown in FIG. 2.

FIG. 7 is a cross-sectional view showing one example of a pixel electrode illustrated in FIG. 6.

FIG. 8 is a schematic cross-sectional view of the line III-III′ shown in FIG. 2.

FIG. 9 is a schematic cross-sectional view of the line IV-IV′ shown in FIG. 2.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only˜’ is used. The terms of a singular form may include plural forms unless referred to the contrary. In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used. It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand.

The embodiments of the present disclosure may be carried out independently from each other or may be carried out together in co-dependent relationship.

Hereinafter, the preferred embodiments of the present disclosure will be described in detail with reference to the accompanying drawings.

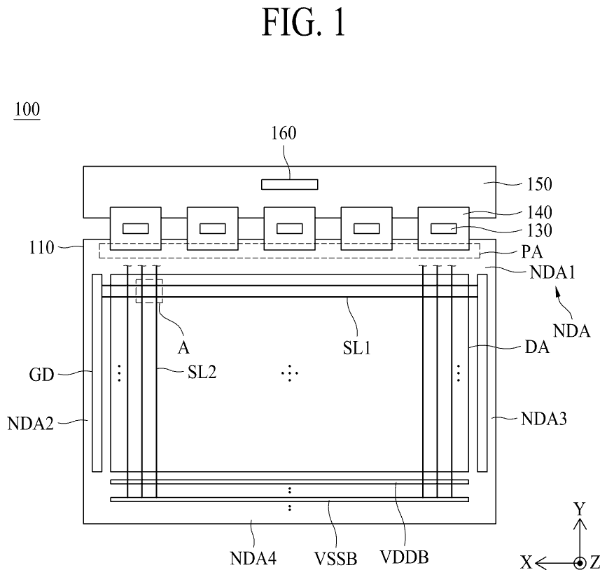

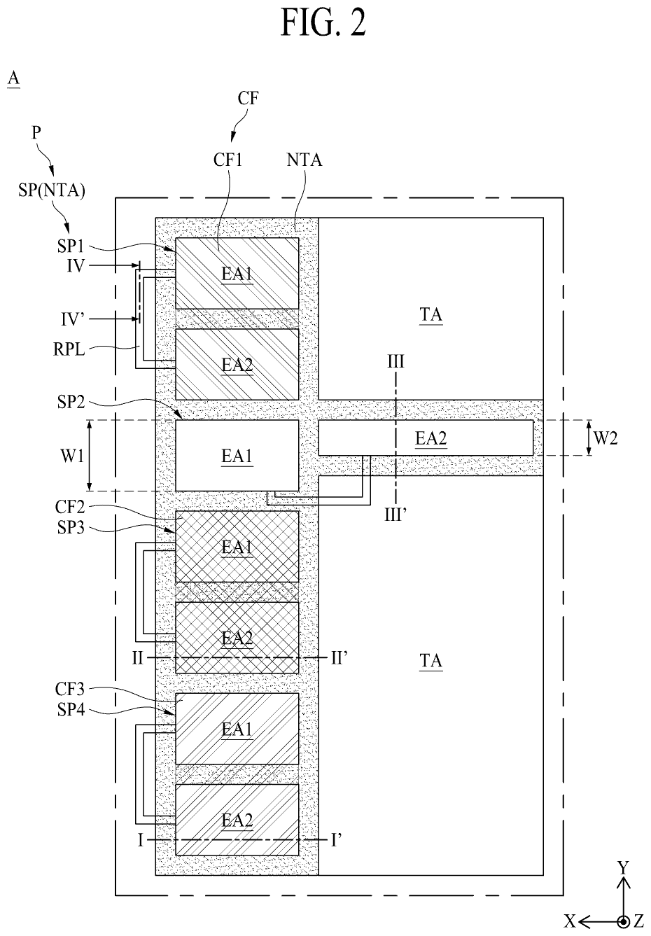

FIG. 1 is a plan view illustrating a transparent display apparatus according to one embodiment of the present disclosure, and FIG. 2 is a schematic enlargement of portion A of FIG. 1, showing a single pixel.

Hereinafter, a first direction (Y-axis direction) represents a direction parallel to a plurality of second signal lines SL2 arranged vertically, a second direction (X-axis direction) represents a direction parallel to a plurality of first signal lines SL1 arranged horizontally, and a third direction (Z-axis direction) represents a thickness direction of the transparent display apparatus 100.

The following description will be based on that a transparent display apparatus 100 according to one embodiment of the present disclosure is an organic light emitting display apparatus, but is not limited thereto. That is, the transparent display apparatus according to one embodiment of the present disclosure may be implemented as any one of a liquid crystal display apparatus, a field emission display apparatus, a quantum dot lighting emitting diode apparatus, and an electrophoretic display apparatus as well as the organic light emitting display apparatus.

Referring to FIGS. 1 and 2, the transparent display apparatus 100 according to one embodiment of the present disclosure may include a display panel (or a transparent display panel) having a gate driver GD, a source drive integrated circuit (hereinafter, referred to as “IC”) 130, a flexible film 140, a circuit board 150, and a timing controller 160.

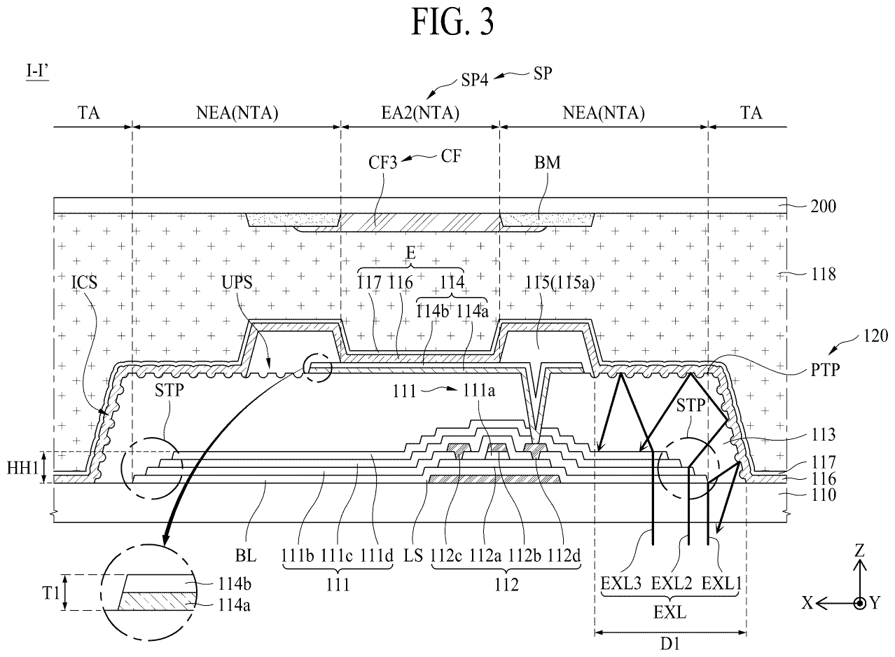

The display panel (or the transparent display panel) may include a substrate 110 and an opposing substrate 200 (shown in FIG. 3), which are bonded to each other.

The substrate 110 may include a thin film transistor, and may be a transistor array substrate, a lower substrate, a base substrate, or a first substrate. The substrate 110 may be a transparent glass substrate or a transparent plastic substrate.

The opposing substrate 200 may be bonded to the substrate 110 via an adhesive member. For example, the opposing substrate 200 may have a size smaller than that of the substrate 110, and may be bonded to the remaining portion except the pad area of the substrate 110. The opposing substrate 200 may be an upper substrate, a second substrate, or an encapsulation substrate.

The gate driver GD supplies gate signals to the gate lines in accordance with the gate control signal input from the timing controller 160. When the source drive IC 130 is manufactured as a driving chip, the source drive IC 130 may be packaged in the flexible film 140 in a chip on film (COF) method or a chip on plastic (COP) method.

Pads such as power pads and data pads may be formed in a non-display area of a display panel. A flexible film 140 may include lines connecting the pads to a source drive IC 130 and lines connecting the pads to lines of a circuit board 150. The flexible film 140 may be attached to the pads by using an anisotropic conducting film, whereby the pads may be connected to the lines of the flexible film 140.

Referring to FIG. 1, the substrate 110 according to one example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

The display area DA according to one example may include gate lines, data lines, pixel driving power lines, and a plurality of pixels P (shown in FIG. 2). Each of the plurality of pixels P may include a plurality of sub-pixels SP that may be defined by the gate lines and the data lines, and a transmissive area TA arranged adjacent to at least some of the subpixels SP among the plurality of subpixels SP. The transmissive area TA is an area provided to allow light to transmit front and rear surfaces of the display panel. Therefore, a user located in the direction of the front surface of the display panel may view an image and a background positioned in the direction of the rear surface of the display panel through the transmissive area TA.

As illustrated in FIG. 2, a remaining portion of the display area DA excluding the transmissive area TA may be a non-transmissive area NTA. The transmissive area TA is an area that allows most of the light incident from the outside to pass through, and the non-transmissive area NTA is an area that does not allow most of the light incident from the outside to pass through.

According to one example, a non-transmissive area NTA may include an area including a light emitting area EA of each of the plurality of subpixels SP, and a black matrix BM (shown in FIG. 3) between the light emission areas EA. The area including the black matrix BM is an area where a light is not emitted, and thus may be included in a non-light emission area NEA (shown in FIG. 3). According to one example, the non-light emission area NEA may be provided between the transmissive area TA and the plurality of sub-pixels SP, and between the plurality of sub-pixels SP on the substrate 110.

Each of the plurality of sub-pixels SP may be defined as a minimum unit area in which light is actually emitted.

The plurality of subpixels SP according to one example may include a plurality of colored subpixels and a white subpixel. The white subpixel may be arranged adjacent to at least some of the plurality of colored subpixels.

For example, as shown in FIG. 2, the plurality of colored subpixels may include a first subpixel SP1 (or a green subpixel SP1), a third subpixel SP3 (or a blue subpixel SP3), and a fourth subpixel SP4 (or a red subpixel SP4) arranged in a column in the first direction (Y-axis direction). The second sub-pixel SP2 (or a white sub-pixel SP2) may have a portion (e.g., the first light emission area EA1) positioned between the first sub-pixel SP1 (or the green sub-pixel SP1) and the third sub-pixel SP3 (or the blue sub-pixel SP3), and a remainder (e.g., a second light emission area EA2) may protrude in the second direction (X-axis direction) and be positioned in the transmissive area TA. As shown in FIG. 2, the transmissive area TA can be divided into two by the second subpixel SP2 (or the second light emission area EA2 of the white subpixel SP2) protruding in the second direction (X-axis direction). For example, the transmissive area TA arranged on an upper side of the second subpixel SP2 (or the second light emission area EA2 of the white subpixel SP2) may be arranged adjacent to each of the first subpixel SP1 (or the green subpixel SP1) and the second subpixel SP2 (or the second light emission area EA2 of the white subpixel SP2) protruding in the second direction (X-axis direction). The transmissive area TA arranged below the second sub-pixel SP2 (or the second light emission area EA2 of the white sub-pixel SP2) can be arranged adjacent to each of the third sub-pixel SP3 (or the blue sub-pixel SP3), the fourth sub-pixel SP4 (or the red sub-pixel SP4), and the second sub-pixel SP2 (or the second light emission area EA2 of the white sub-pixel SP2) protruding in the second direction (X-axis direction). Therefore, in the transparent display apparatus 100 according to one embodiment of the present disclosure, the plurality of subpixels SP included in one pixel P may be provided in a pinwheel structure (or a windmill structure).

However, it is not limited thereof, an arrangement structure of the plurality of sub-pixels SP can be varied.

As shown in FIG. 2, each of the plurality of colored subpixels and the white subpixel may include a first light emission area EA1 and a second light emission area EA2 that are arranged spaced apart from each other. For example, each of the first subpixel SP1 (or the green subpixel SP1), the second subpixel SP2 (or the white subpixel SP2), the third subpixel SP3 (or the blue subpixel SP3), and the fourth subpixel SP4 (or the red subpixel SP4) may be provided with two light emission areas (e.g., the first light emission area EA1 and the second light emission area EA2 spaced apart from each other).

Hereinafter, one example will be described in which one unit pixel P of the transparent display apparatus 100 according to one embodiment of the present disclosure includes four subpixels SP1, SP2, SP3, SP4 arranged in the pinwheel shape and two divided transmissive areas TA.

Each of the plurality of sub-pixels SP may include a thin film transistor and a light emitting element connected to the thin film transistor. The sub-pixel may include a light emitting layer (or an organic light emitting layer) interposed between a first electrode and a second electrode.

The light emitting layer disposed in each of the plurality of sub-pixels SP may individually emit light of different colors, or may commonly emit white light. According to one example, when the light emitting layer of each of the plurality of sub-pixels SP1, SP2, SP3, SP4 commonly emits white light, each of the red sub-pixel, the green sub-pixel and the blue sub-pixel may include a color filter (or a wavelength conversion member) for converting the white light into light of different colors. In this case, the white sub-pixel according to one example may not include a color filter. The color filter CF, according to one example, can include a green color filter CF1, a blue color filter CF2, and a red color filter CF3.

Each of the plurality of sub-pixels SP supplies a predetermined current to the organic light emitting element in accordance with a data voltage of the data line when a gate signal is input from the gate line by using the thin film transistor. For this reason, the light emitting layer of each of the sub-pixels may emit light with a predetermined brightness in accordance with the predetermined current.

As shown in FIG. 1, in the light emission area EA, the plurality of pixels and a plurality of lines for driving each of the plurality of pixels can be disposed. The plurality of lines, according to one example, can include a plurality of first signal lines SL1 and a plurality of second signal lines SL2.

The plurality of first signal lines SL1 may be extended in the second direction (X-axis direction). Each of the plurality of first signal lines SL1 may include at least one scan line (or gate line).

Hereinafter, when the first signal line SL1 includes a plurality of lines, one first signal line SL1 may refer to a signal line group comprised of a plurality of lines. For example, when the first signal line SL1 includes two scan lines, one first signal line SL1 may refer to a signal line group comprised of two scan lines.

The plurality of second signal lines SL2 can extend in the first direction (Y-axis direction). The plurality of second signal lines SL2 can intersect with the plurality of first signal lines SL1. The plurality of second signal lines SL2 according to one embodiment can include a pixel power line, and a common power line, a plurality of data lines, and a reference line.

Hereinafter, when the second signal line SL2 includes a plurality of lines, one second signal line SL2 may refer to a signal line group comprised of a plurality of lines. For example, when the second signal line SL2 includes four data lines, a pixel power line, a common power line and a reference line, one second signal line SL2 may refer to a signal line group comprised of four data lines, the pixel power line, the common power line and the reference line.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA.

The transparent display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. The non-display area NDA can include a first non-display area NDA1, a second non-display area NDA2, a third non-display area NDA3, and a fourth non-display area NDA4. The pad portion PA according to one example can be disposed in the first non-display area NDA1.

The gate driver GD supplies gate signals to the gate lines in accordance with the gate control signal input from the timing controller 160. The gate driver GD may be formed on one side of the display area DA of the display panel or on the non-display area NDA outside both sides of the display area DA in a gate driver in panel (GIP) method as shown in FIG. 1. Alternatively, the gate driver GD may be manufactured as a driving chip, packaged in a flexible film and attached to the non-display area NDA outside one side or both sides of the display area DA of the display panel by a tape automated bonding (TAB) method.

The plurality of gate drivers GD may be separately disposed on a left side of the display area DA, that is, the second non-display area NDA2 and a right side of the display area DA, that is, the third non-display area NDA3. According to one example, the plurality of gate drivers GD may be connected to the plurality of pixels P and the plurality of first signal lines SL1 for supplying signals to the plurality of pixels P. The plurality of first signal lines SL1 may include at least one signal line for supplying a signal for driving the pixel P.

Each of the plurality of second signal lines SL2 may be connected to at least one of a plurality of pads, a pixel power shorting bar VDDB and a common power shorting bar VSSB. The pixel power shorting bar VDDB and the common power shorting bar VSSB may be disposed in the fourth non-display area NDA4 that is disposed to face the pad area PA based on the display area DA.

The pixels are provided to overlap at least one of the first signal line SL1 and the second signal line SL2 and emit predetermined light to display an image. The light emission area EA may correspond to an area, which emits light, in the pixel P.

Each of the green sub-pixel SP1 (or first sub-pixel SP1), the white sub-pixel SP2 (or second sub-pixel SP2), the blue sub-pixel SP3 (or third sub-pixel SP3), and the red sub-pixel SP4 (or fourth sub-pixel SP4) can comprise two light emission areas. Two light emission area of each of the sub-pixels SP1, SP2, SP3, SP4 can have the same shape and size, but is not necessarily limited thereto.

The non-light emission area NEA may refer to an area that is provided in the display area DA and does not emit light, and may be expressed as a dead zone because it does not emit light. The dead zone according to one example may be an area in which a black matrix and/or a bank is provided, but is not limited thereto, and may refer to an area in which light is not emitted.

The non-light emission area NEA can have the plurality of lines, for example, first signal lines SL1 and second signal lines SL2 can be disposed. The first signal lines SL1 according to one example can include the gate line disposed extending in the second direction (X-axis direction). The second signal lines SL2 according to one example can include the pixel power line, the common power line, the reference line, and the plurality of data lines, which are extending in the first direction (Y-axis direction).

Hereinafter, the transparent display apparatus 100 according to one embodiment of the present disclosure will be described in more detail with reference to FIGS. 3 to 5.

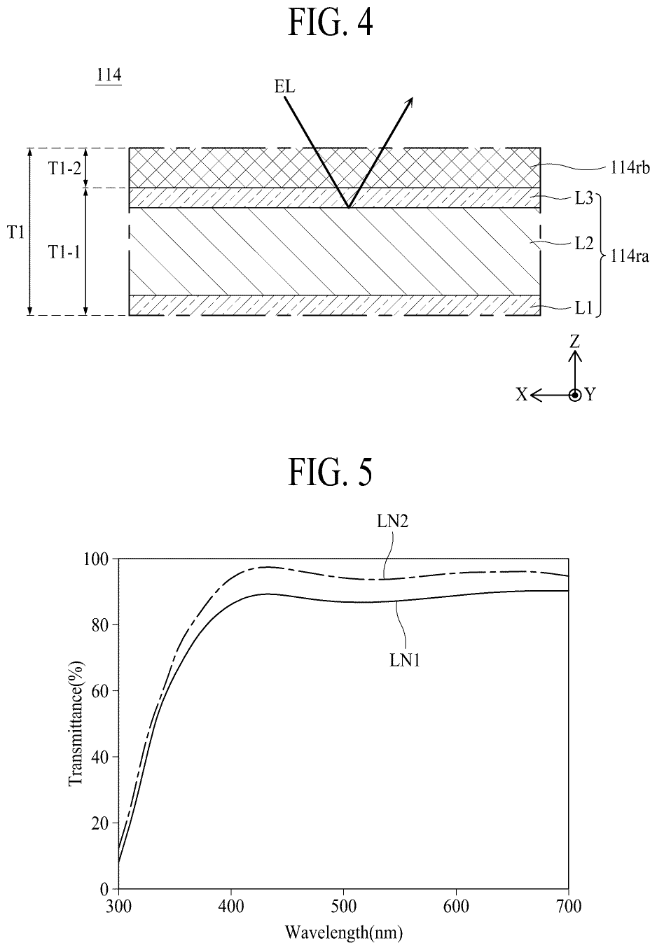

FIG. 3 is a schematic cross-sectional view of the line I-I′ shown in FIG. 2, FIG. 4 is a cross-sectional view showing one example of a pixel electrode illustrated in FIG. 3, and FIG. 5 is a schematic graph showing the transmittance according to wavelength of a transparent display apparatus according to one embodiment of the present disclosure.

Referring to FIG. 3, the transparent display apparatus 100 according to one embodiment of the present disclosure may include the substrate 110, the plurality of inorganic films 111, the planarization layer 113, and the light path changing patterned structure 120 (also referred to as the light path changing portion 120).

The substrate 110 according to one example may include a transmissive area TA and a non-transmissive area NTA. The non-transmissive area NTA may be adjacent to the transmissive area TA. And the plurality of subpixels SP may be placed in the non-transmissive area NTA.

The plurality of inorganic films 111 according to one example are provided in the non-transmissive area NTA and may have a step STP. For example, the plurality of inorganic films 111 may include a gate insulating layer 111a, an interlayer insulating layer 111b, a first passivation layer 111c, and a second passivation layer 111d. The plurality of inorganic films 111 may further include a buffer layer BL. The gate insulating layer 111a, the interlayer insulating layer 111b, the first passivation layer 111c, and the second passivation layer 111d can be disposed on the buffer layer BL.

As shown in FIG. 3, the plurality of inorganic films 111 may have the step STP due to a process margin. For example, a width of the buffer layer BL arranged closest to the substrate 110 may be provided to be the widest. In addition, a width of each of the interlayer insulating layer 111b, the first passivation layer 111c, and the second passivation layer 111d sequentially laminated on the buffer layer BL may be provided to become narrower as it goes upward (or in a direction from the substrate 110 toward the opposing substrate 200). Accordingly, edges of the plurality of inorganic films 111 may have the step STP.

In the case of a general transparent display apparatus, since a transmissive area is arranged adjacent to the edges of a plurality of inorganic films, a light passing through the transmissive area (or a light incident on the substrate adjacent to the transmissive area) may be diffracted by the steps STP of the plurality of inorganic films, thereby increasing the haze value. Therefore, in the case of the general transparent display apparatus, a clarity of an object or an image may be reduced due to the steps STP of the plurality of inorganic films.

In contrast, the transparent display apparatus 100 according to one embodiment of the present disclosure includes the planarization layer 113 covering the plurality of inorganic films 111 (or the steps STP of the plurality of inorganic films 111) adjacent to the transmissive area TA, and the planarization layer 113 is provided to partially include the light path changing portion 120, so that diffraction of light (or a light incident on the substrate adjacent to the transmissive area) passing through the transmissive area TA can be prevented, thereby improving the clarity of the object or the image shown to a user through the transmissive area TA.

For example, the light path changing portion 120 may include a plurality of pattern portions PTP. The plurality of pattern portions PTP may be regular or irregular. As shown in FIG. 3, the plurality of pattern portions PTP may be provided in a convex and concave shape. In FIG. 3, the plurality of pattern portions PTP are illustrated as being provided in a regular shape, but they may be provided in an irregular shape if diffraction of light can be prevented. For example, the plurality of pattern portions PTP may be a roughness.

Meanwhile, the light path changing portion 120 may be provided on each of an upper surface UPS and an inclined surface ICS of the planarization layer 113 adjacent to the transmissive area TA. For example, the upper surface UPS of the planarization layer 113 may be a surface disposed in the uppermost direction in the planarization layer 113. The inclined surface ICS of the planarization layer 113 is connected to the upper surface UPS and may be a sloping surface. The inclined surface ICS of the planarization layer 113 may form an obtuse angle with the upper surface UPS of the planarization layer 113. The planarization layer 113 adjacent to the transmissive area TA may mean a part of the planarization layer 113 arranged on a left side and a part of the planarization layer 113 arranged on a right side based on a boundary between the non-transmissive area NTA and the transmissive area TA, as shown in FIG. 3. For example, with respect to the boundary between the inclined surface ICS and the upper surface UPS of the planarization layer 113 on the right side of FIG. 3, a portion of the planarization layer 113 arranged on the left side of the boundary may mean the planarization layer 113 between the bank 115 and the boundary. A portion of the planarization layer 113 arranged on the right side of the boundary surface may refer to the planarization layer 113 between the boundary surface and an end (or a right end) of the planarization layer 113.

According to one embodiment of the present disclosure, the transparent display apparatus 100 includes the light path changing portion 120 (or the plurality of pattern portions PTP) provided on each of the upper surface UPS and the inclined surface ICS of the planarization layer 113 adjacent to the transmissive area TA, so that light passing through the transmissive area TA (or light incident on the substrate 110 adjacent to the transmissive area TA) is reflected toward the substrate 110, thereby preventing diffraction.

For example, as shown in FIG. 3, external light incident on the substrate 110 adjacent to the transmissive area TA may include a first external light EXL1, a second external light EXL2, and a third external light EXL3.

For example, the first external light EXL1 may be incident on the substrate 110, refracted at an edge of the buffer layer BL, and then reflected by the light path changing portion 120 (or the plurality of pattern portions PTP) provided on the inclined surface ICS of the planarization layer 113 and then emitted to the substrate 110.

For example, the second external light EXL2 may be incident on the substrate 110, refracted at the interlayer insulating layer 111b (or a boundary between the interlayer insulating layer 111b and the planarization layer 113), and then reflected for the first time by the light path changing portion 120 (or the plurality of pattern portions PTP) provided on the inclined surface ICS of the planarization layer 113, reflected for the second time by the light path changing portion 120 (or the plurality of pattern portions PTP) provided on the upper surface UPS of the planarization layer 113, and then emitted to the substrate 110 or totally reflected and extinguished inside the substrate 110.

For example, the third external light EXL3 may be incident on the substrate 110, refracted at the second passivation layer 111d (or a boundary between the second passivation layer 111d and the planarization layer 113), and then reflected for the first time by the light path changing portion 120 (or the plurality of pattern portions PTP) provided on the upper surface UPS of the planarization layer 113, and then emitted to the substrate 110 or totally reflected and extinguished inside the substrate 110.

As a result, in the transparent display apparatus 100 according to one embodiment of the present disclosure, the plurality of pattern portions PTP can change a light path of at least a portion of external light EXL incident through the substrate 110 or the plurality of inorganic films 111 toward the substrate 110. Accordingly, the transparent display apparatus 100 according to one embodiment of the present disclosure can prevent diffraction, thereby improving a clarity of an object or an image shown to a user through the transmissive area TA.

In the above, it was described that the light path changing portion 120 (or the plurality of pattern portions PTP) reflects light to change a path of light, but it is not limited thereto. Light (or light incident on the substrate 110 adjacent to the transmissive area) passing through the transmissive area TA may be reflected at an interface between the light path changing portion 120 (or the plurality of pattern portions PTP) and the organic light emitting layer 116, thereby changing a light path.

As a result, the transparent display apparatus 100 according to one embodiment of the present disclosure has the light path changing portion 120 (or the plurality of pattern portions PTP) having a roughness (or a rough structure) between the planarization layer 113 and the organic light-emitting layer 116, so that the light path of light (or light incident on the substrate 110 adjacent to the transmissive area) passing through the transmissive area TA can be changed, and thus a clarity of an object or an image shown to the user can be improved.

Hereinafter, with reference to FIG. 3, the structure of each of the plurality of sub-pixels SPs will be described in detail.

Referring to FIG. 3, a transparent display apparatus 100 according to one embodiment of the present disclosure can include a plurality of inorganic films 111, a thin film transistor 112, a planarization layer 113, a pixel electrode 114, a bank 115, an organic light emitting layer 116, an opposing electrode 117, an encapsulation layer 118, a color filter CF, and a black matrix BM.

In more detail, each of the subpixels SP according to one embodiment may include a plurality of inorganic films 111 provided on an upper surface of a buffer layer BL, including a gate insulating layer 111a, an interlayer insulating layer 111b, a first passivation layer 111c, and a second passivation layer 111d, an planarization layer 113 provided on the plurality of inorganic films 111, a pixel electrode 114 provided on the planarization layer 113, a bank 115 covering an edge of the pixel electrode 114, an organic light emitting layer 116 on the pixel electrode 114 and the bank 115, an opposing electrode 117 on the organic light emitting layer 116, an encapsulation layer 118 on the opposing electrode 117, and the color filter CF and the black matrix BM on the encapsulation layer 118.

The thin film transistor 112 for driving the subpixel SP may be disposed on the plurality of inorganic films 111. The plurality of inorganic films 111 may be expressed as the term of a circuit element layer. The buffer layer BL may be included in the plurality of inorganic films 111 together with the gate insulating layer 111a, the interlayer insulating layer 111b, the first passivation layer 111c, and the second passivation layer 111d. The pixel electrode 114, the organic light emitting layer 116 and the opposing electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape only on the channel area of the active layer 112a, or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. The interlayer insulating layer 111b may be formed in a circuit area equipped with the thin film transistor and an entire light emission area in which light is emitted to the subpixel SP. However, embodiments of the present disclosure are not limited thereto, the interlayer insulating layer 111b may be patterned between the drain electrode 112d and the gate electrode 112b and drain region of the active layer 112a and may be arranged in an island shape, and moreover, may be patterned between the source electrode 112c and the gate electrode 112b and source region of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor (not shown) may be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 may further include a light shielding layer (LS) provided below the active layer 112a of at least one of the thin film transistor 112, the first switching thin film transistor and the second switching thin film transistor. The light shielding layer may be disposed between the substrate 110 and the active layer 112a to shield light incident on the active layer 112a through the substrate 110, thereby reducing or minimizing a change in the threshold voltage of the transistor due to external light. Also, since the light shielding layer is provided between the substrate 110 and the active layer 112a, the thin film transistor may be prevented from being seen by a user.

The first passivation layer 111c may be provided on the substrate 110 to cover the pixel area. The first passivation layer 111c covers a drain electrode 112d, a source electrode 112c and a gate electrode 112b of the thin film transistor 112, and the buffer layer BL.

The second passivation layer 111d may be provided on the substrate 110 to cover the first passivation layer 111c. The planarization layer 113 may be arranged on the second passivation layer 111d. As described above, a width of each of the buffer layer BL, the interlayer insulating layer 111b, the first passivation layer 111c, and the second passivation layer 111d included in the plurality of inorganic films 111 may be configured to become narrower in the upward direction due to the process margin. Accordingly, as shown in FIG. 3, the plurality of inorganic films 111 adjacent to the transmissive area TA may have the step STP. The step STP according to one example may have a first height HH1. The first height HH1 may be a thickness of the plurality of inorganic films 111.

The planarization layer 113 may be provided on the substrate 110 to cover the plurality of inorganic films 111. For example, the planarization layer 113 may be formed to extend further toward the transmissive area TA, thereby covering the step STP formed by the plurality of inorganic films 111. According to one example, the planarization layer 113 may be placed between the substrate 110 and the pixel electrode 114. When the passivation layer 111c is omitted, the planarization layer 113 may be provided on the substrate 110 to cover the circuit area. The planarization layer 113 may be formed in the circuit area in which the thin film transistor 112 is disposed and the light emission area EA. In addition, the planarization layer 113 may be formed in the other non-display area NDA except a pad area PA of the non-display area NDA and the entire display area DA. For example, the planarization layer 113 may include an extension portion (or an enlarged portion) extended or enlarged from the display area DA to the other non-display area NDA except the pad area PA. Therefore, the planarization layer 113 may have a size relatively wider than that of the display area DA.

The planarization layer 113 according to one example may be formed to have a relatively thick thickness, thereby providing a flat surface on the display area DA and the non-display area NDA. For example, the planarization layer 113 may be made of an organic material such as photo acryl, benzocyclobutene, polyimide and fluorine resin.

Meanwhile, the planarization layer 113 may be provided to cover the plurality of inorganic films 111. Accordingly, as shown in FIG. 3, the planarization layer 113 may cover the step STP of the plurality of inorganic films 111 adjacent to the transmissive area TA. Therefore, an edge of the planarization layer 113 can be placed in a boundary area between the step STP of the plurality of inorganic films 111 and the transmissive area TA.

The planarization layer 113 may be provided to partially include the light path changing portion 120 (or the plurality of pattern portions PTP). For example, as shown in FIG. 3, the planarization layer 113 arranged in a boundary area between the step STP of the plurality of inorganic films 111 and the transmissive area TA may be provided to include the light path changing portion 120 (or the plurality of pattern portions PTP) such as roughness. For example, the light path changing portion 120 (or the plurality of pattern portions PTP) may be provided on each of the upper surface UPS and the inclined surface ICS of the planarization layer 113 adjacent to the transmissive area TA.

Therefore, the transparent display apparatus 100 according to one embodiment of the present disclosure is provided with the light path changing portion 120 (or the plurality of pattern portions PTP) on each of the upper surface UPS and the inclined surface ICS of the planarization layer 113 adjacent to the transmissive area TA, so that light passing through the transmissive area TA (or light incident on the substrate adjacent to the transmission area) is reflected toward the substrate 110, thereby preventing diffraction.

The pixel electrode 114 included in each of the plurality of subpixels SP may be partially disposed on the upper surface of the planarization layer 113. For example, the pixel electrode 114 may be disposed on the upper surface of the planarization layer 113 that is provided flatly and does not have the light path changing portion 120. This is because the pixel electrode 114 is formed on the upper surface of the planarization layer 113 that is provided flat before the ashing process for forming the light path changing portion 120. Due to this, the pixel electrode 114 positioned on the upper surface of the planarization layer 113 can also be provided flatly, and the organic light-emitting layer 116 and the opposing electrode 117 formed thereon can also be provided in a flat form. Since the pixel electrode 114, the organic light-emitting layer 116, and the opposing electrode 117, i.e., the light-emitting element layer E, are provided flatly in the light emission area EA, a thicknesses of each of the pixel electrode 114, the organic light-emitting layer 116, and the opposing electrode 117 can be formed uniformly within the light emission area EA. Accordingly, the organic light-emitting layer 116 can emit light uniformly without deviation within the light emission area EA.

The pixel electrode 114 can be connected to the drain electrode or source electrode of the thin film transistor 112 through a contact hole penetrating the planarization layer 113, the second passivation layer 111d, and the first passivation layer 111c. The edge portion of the pixel electrode 114 can be covered by the bank 115.

Since the transparent display apparatus 100 according to one embodiment of the present disclosure is top-emission type, the pixel electrodes 114 can be made of a highly reflective metallic material or a stacked structure of a highly reflective metallic material and a transparent metallic material. For example, the first electrode 114 may be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy may be an alloy such as silver (Ag), palladium (Pd), and copper (Cu). The pixel electrode 114 may be a first electrode or an anode electrode. In the transparent display apparatus 100 according to one embodiment of the present disclosure, the pixel electrode 114 may be provided with a laminated structure of ITO/Ag/ITO.

The bank 115 may be an area, which does not emit light, and disposed on both side of the light emission area EA of each of the plurality of sub-pixels SP. As shown in FIG. 3, the bank 115 may partially cover the pixel electrode 114. For example, the bank 115 may cover an edge of the pixel electrode 114 (or one edge and the other edge of the pixel electrode 114). Accordingly, the bank 115 may prevent the pixel electrode 114 and the opposing electrode 117 in the edge of the pixel electrode 114 to be contacted. The exposed portion of the pixel electrode 114 that is not covered by the bank 115 may be included in the light emitting portion (or light emission area EA).

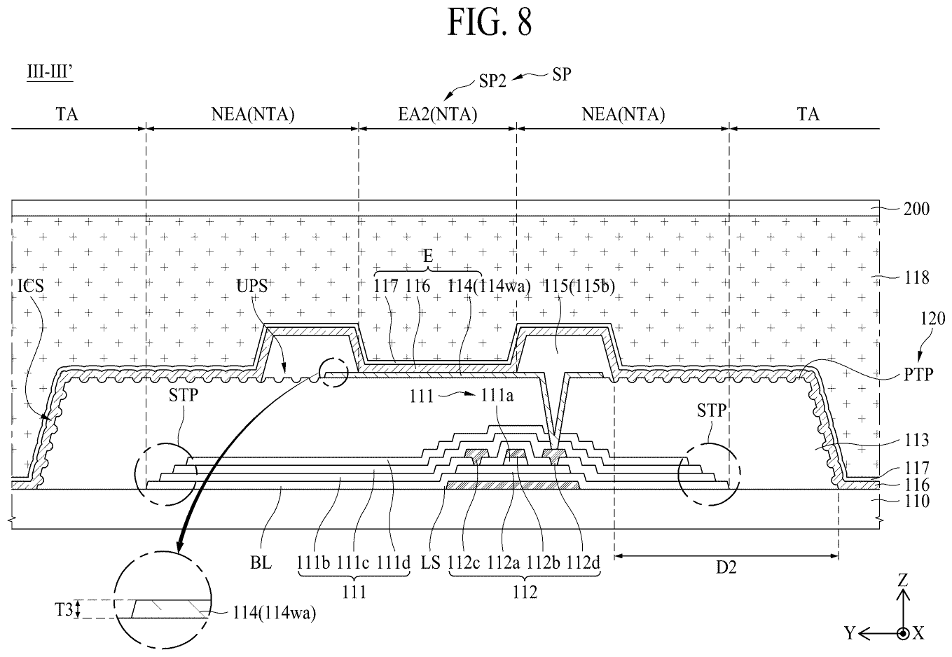

After the bank 115 is formed, an organic light emitting layer 116 may be formed to cover the pixel electrodes 114 and the bank 115. Thus, the bank 115 may be partially provided between the pixel electrodes 114 and the organic light emitting layer 116. The bank 115 may be expressed in terms of a pixel-defining membrane. The bank 115 according to one example may comprise organic material and/or inorganic material. In a transparent display apparatus 100 according to one embodiment of the present disclosure, the bank 115 may include a first bank 115a and a second bank 115b (shown in FIG. 8). The first bank 115a may be a bank adjacent to the second light emission area EA2 of one (e.g., the red sub-pixel SP4) of the plurality of color sub-pixels. The second bank 115b may be a bank adjacent to the second light emission area EA2 of the white sub-pixel SP2.

Meanwhile, in the transparent display apparatus 100 according to one embodiment of the present disclosure, the bank 115 may partially cover the light path changing portion 120. This is because, after the pixel electrode 114 is formed on the planarization layer 113, an ashing process is performed to form the light path changing portion 120, and then the bank 115 is formed. If the ashing process is performed after the planarization layer 113 is formed (or before the formation of the pixel electrode 114), the upper surface of the planarization layer 113 on which the pixel electrode 114 is placed also has the light path changing portion 120 (or an uneven structure), so the pixel electrode cannot be formed flat. In this case, since the organic light-emitting layer 116 and the opposing electrode 117 on the pixel electrode 114 are also formed along the uneven structure of the pixel electrode 114, a reflectivity of the pixel electrode 114 can be reduced.

The following Table 1 is a result of simulating a reflectivity of the pixel electrode 114 when an ashing process is performed on the planarization layer 113 before the formation of the pixel electrode 114, and a reflectivity of the pixel electrode 114 when the ashing process is not performed on the planarization layer 113, by wavelength (or from short wavelength to long wavelength).

TABLE 1

| Ashing | 420 nm | 550 nm | 680 nm | Avg. |
|---|---|---|---|---|
| X | 78.8 | 91.8 | 92.7 | 89.6 |
| ◯ | 60.2 | 72.9 | 80.6 | 74.1 |

If an ashing process is performed on the planarization layer 113 before the formation of the pixel electrode 114, a rough structure (or a roughness) is formed on the planarization layer 113 beneath the pixel electrode 114, so the pixel electrode 114 formed in the subsequent process can also be formed along the rough structure. Therefore, in this case, it can be seen that the reflectivity of the pixel electrode 114 has a value of about 60 to about 74.

In contrast, when the ashing process for the planarization layer 113 is not performed, the pixel electrode 114 is formed on an upper surface of the planarization layer 113 that is provided flatly, so that the pixel electrode 114 can also be provided flatly. Accordingly, in this case, it can be seen that the reflectivity of the pixel electrode 114 has a value of about 78 to about 89.

As shown in Table 1 above, it can be seen that the reflectivity of the pixel electrode 114 formed with the rough structure is about 10 lower from short wavelength to long wavelength than the reflectivity of the pixel electrode 114 formed flatly.

According to one embodiment of the present disclosure, the transparent display apparatus 100 performs the ashing process after the pixel electrode 114 is formed on a flat planarization layer 113, so that the pixel electrode 114 can be formed flat, and thus the reflectivity of the pixel electrode 114 can be further improved compared to a case where the ashing process is performed before the formation of the pixel electrode 114.

In addition, since the transparent display apparatus 100 according to one embodiment of the present disclosure performs the ashing process after the pixel electrode 114 is formed on the planarization layer 113 that is provided flatly, the upper surface of the planarization layer 113 under the pixel electrode 114 can be provided flatly, and can have a structural feature in which the bank 115 formed in the subsequent process is provided to partially cover the light path changing portion 120. Here, the light path changing portion 120 covered by the bank 115 may mean a light path changing portion 120 formed on the planarization layer 113 adjacent to an edge of the pixel electrode 114. The ashing process according to one example may be performed using a process gas containing fluorine (F).

The organic light emitting layer 116 may be formed on the pixel electrodes 114 and the bank 115. According to one example, the organic light emitting layer 116 may be disposed in the light emission area EA, the non-light emission area NEA, and the transmissive area TA. The organic light emitting layer 116 may be provided between the pixel electrode 114 and the opposing electrode 117. Thus, when a voltage is applied to each of the pixel electrode 114 and the opposing electrode 117, an electric field is formed between the pixel electrode 114 and the opposing electrode 117. Therefore, the organic light emitting layer 116 may emit light. The organic light emitting layer 116 may be formed of a plurality of subpixels SP and a common layer provided on the bank 115.

The organic light emitting layer 116 according to one embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The organic light emitting layer 116 may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), a blue emission layer (EML (B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML (YG)), and an electron injection layer (EIL) are sequentially stacked.

In the display apparatus 100 according to one embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The opposing electrode 117 may be formed on the organic light emitting layer 116. The opposing electrode 117 may be disposed in the light emission area EA, the non-light emission area NEA, and the transmissive area TA. The opposing electrode 117 according to one example may include a metal material. The opposing electrode 117 may reflect the light emitted from the organic light emitting layer 116 in the plurality of subpixels SP toward the lower surface of the substrate 110. Therefore, the display apparatus 100 according to one embodiment of the present disclosure may be implemented as a bottom emission type display apparatus.

Since the transparent display apparatus 100 according to one embodiment of the present disclosure is top-emission type, the opposing electrodes 117 can be formed of a transparent conductive material TCO such as ITO, IZO, that is capable of transmitting light or a semi-transmissive conductive material TMCM such as magnesium (Mg), silver (Ag), or an alloy of magnesium (Mg) and silver (Ag). Such opposing electrodes 117 can be referred in terms of second electrodes, cathode electrodes.

The encapsulation layer 118 is formed on the opposing electrodes 117. The encapsulation layer 118 serves to prevent oxygen or moisture from penetrating into the organic light emitting layer 116 and the opposing electrodes 117. To this end, the encapsulating layer 118 may include at least one inorganic film and at least one organic film.

Meanwhile, as shown in FIG. 3, the encapsulation layer 118 may be placed not only in the light emission area EA but also in the non-light emission area NEA. In addition, the encapsulation layer 118 may be placed in the transmission area TA. The encapsulation layer 118 may be placed between the opposing electrode 117 and the opposing substrate 200.

A color filter CF and a black matrix BM can be disposed between the encapsulation layer 118 and the opposing substrate 200. As described above, the white subpixel SP2 may not be provided with the color filter because the organic light-emitting layer 116 emits white light. On the other hand, the first color filter CF1 (or the green color filter CF1) may be provided between the encapsulation layer 118 and the opposing substrate 200 in the green subpixel SP1. In the blue subpixel SP3, the second color filter CF2 (or the blue color filter CF2) may be provided between the encapsulation layer 118 and the opposing substrate 200. The third color filter CF3 (or the red color filter CF3) may be provided between the encapsulation layer 118 and the opposing substrate 200 in the red subpixel SP4. As shown in FIG. 3, the color filter CF may be provided to partially cover the black matrix BM.

On the other hand, the black matrix BM can be provided between the plurality of sub-pixels SP1, SP2, SP3, SP4 to prevent color mixing and/or light leakage. However, in order to improve an area of the transmissive area TA, the black matrix BM may not be placed between the second subpixel SP2 (or the second light emission area EA2 of the white subpixel SP2) and the transmissive area TA (shown in FIG. 8). Since the second subpixel SP2 is equipped to emit white light, color mixing may not occur even if there is no black matrix BM between the second subpixel SP2 and the transmissive area TA. Accordingly, the transparent display apparatus 100 according to one embodiment of the present disclosure may have a structural feature in which the black matrix BM is not placed between the second subpixel SP2 (or the second light emission area EA2 of the white subpixel SP2) and the transmissive area TA.

The black matrix BM can comprise a black colored material. At least a portion of the black matrix BM may be arranged to overlap with the bank 115. The area provided with the black matrix BM and/or the bank 115 can be a dead zone or the non-light emission area NEA (or a non-transmissive area NTA). The black matrix BM according to one example can be formed on an opposing substrate 200 to overlap at least a portion of the bank 115, thereby reducing the cell gap between the organic light emitting layer 116 and the opposing substrate 200 to prevent color mixing of sub-pixels.

Meanwhile, in the transparent display apparatus 100 according to one embodiment of the present disclosure, the pixel electrode 114 including the red subpixel SP4 may be provided as follows.

For example, as shown in FIG. 4, the pixel electrode 114 of the red subpixel SP4 may include a first red pixel electrode 114ra and a second red pixel electrode 114rb. The second red pixel electrode 114rb may be disposed on the first red pixel electrode 114ra. The first red pixel electrode 114ra according to one example may include a first layer L1, a second layer L2, and a third layer L3 that are sequentially laminated. The first layer L1 may be ITO. The second layer L2 may be Ag. The third layer L3 may be ITO. However, it is not limited thereto, and if it has a work function capable of emitting light from the organic light-emitting layer 116 and can reflect light emitted from the organic light-emitting layer 116 toward the opposing substrate 200, the first layer L1, the second layer L2, and the third layer L3 can each be formed of different materials.

The second red pixel electrode 114rb may be placed on the third layer L3. The second red pixel electrode 114rb is for adjusting the resonance distance of the micro cavity to improve light extraction efficiency.

The microcavity characteristic refers to a characteristic in which constructive interference occurs when the distance between the second layer L2 and the opposing electrode 117 becomes an integer multiple of the half wavelength (2/2) of light emitted from the subpixel, and the light is amplified, and when the reflection and re-reflection process is repeated between the second layer L2 and the opposing electrode 117, the degree of light amplification continuously increases, thereby improving the external extraction efficiency of light.

According to one embodiment of the present disclosure, the transparent display apparatus 100 can implement a resonance distance for implementing micro-cavity characteristics by having the second red pixel electrode 114rb disposed on the first red pixel electrode 114ra, thereby improving the light extraction efficiency of the red subpixel SP4.

Meanwhile, in the transparent display apparatus 100 according to one embodiment of the present disclosure, the pixel electrode 114 included in the red subpixel SP4 may include fluorine (F). For example, the second red pixel electrode 114rb of the pixel electrode 114 included in the red subpixel SP4 may include fluorine (F). As described above, after the pixel electrode 114 is formed on the planarization layer 113, an ashing process (or an ashing process using fluorine process gas) is performed to form the light path change portion 120, so that the second red pixel electrode 114rb located at an uppermost side of the pixel electrode 114 may include fluorine (F). For example, if the second red pixel electrode 114rb before the ashing process is ITO, the second red pixel electrode 114rb after the ashing process may be FTO containing fluorine. Accordingly, the transparent display apparatus 100 according to one embodiment of the present disclosure may have a feature in which the second red pixel electrode 114rb located at the uppermost side among the pixel electrodes 114 arranged in the red subpixel SP4 is provided with FTO.

When the second red pixel electrode 114rb is formed of FTO, the transmittance of light emitted from the organic light-emitting layer 116 and reflected by the second layer L2 can be improved. This will be described in conjunction with FIG. 5.

Referring to FIG. 5, LN1 is a graph of light transmittance according to wavelength of a pixel electrode made of ITO of a general transparent display apparatus, and LN2 is a graph of light transmittance according to wavelength of the pixel electrode 114 made of FTO of the transparent display apparatus 100 according to one embodiment of the present disclosure. A horizontal axis represents a wavelength, and a vertical axis represents the light transmittance of the pixel electrode 114. As shown in FIG. 5, in the case of a general transparent display apparatus, it can be seen that the light transmittance increases to about 88% up to about 430 nm and then remains almost horizontal at wavelengths greater than 430 nm. In contrast, in the case of the transparent display apparatus 100 according to one embodiment of the present disclosure, it can be seen that the light transmittance increases to about 98% up to about 430 nm and then remains almost horizontal at wavelengths greater than 430 nm. This may mean that the light transmittance of the pixel electrode 114 including fluorine (F) is higher than the light transmittance of the pixel electrode not including fluorine. For example, as shown in FIG. 5, it can be seen that the light transmittance of the pixel electrode 114 including fluorine (F) is about 5% to 10% higher than the light transmittance of the pixel electrode not including fluorine.

If the light transmittance of the pixel electrode 114 (or the second red pixel electrode 114rb) including fluorine (F) is high, as shown in FIG. 4, the light transmittance of the light EL of the organic light-emitting layer 116 reflected by the second layer L2 (or the light EL emitted from the organic light-emitting layer 116) passing through the second red pixel electrode 114rb can be high, and thus the light extraction efficiency of the red subpixel SP4 can be improved.

Therefore, the transparent display apparatus 100 according to one embodiment of the present disclosure is provided such that the pixel electrode 114 (or the second red pixel electrode 114rb included in the red subpixel SP4) includes fluorine (F), thereby satisfying the microcavity resonance distance and improving the light transmittance, so that the light extraction efficiency (or the light extraction efficiency of the red subpixel SP4) can be improved.

Meanwhile, as shown in FIG. 3, the pixel electrode 114 included in the red subpixel SP4 may be provided with a first thickness T1. For example, as shown in FIG. 4, the first thickness T1 may be a thickness obtained by adding the thickness T1-1 of the first red pixel electrode 114ra and a thickness T1-2 of the second red pixel electrode 114rb. The thickness T1-1 of the first red pixel electrode 114ra may be a sum of a thicknesses of each of the first layer L1, the second layer L2, and the third layer L3. Here, the thickness of the second layer L2 may be thicker than the thickness of the first layer L1 (or the third layer L3). This is because the second layer L2 must reflect light emitted from the organic light-emitting layer 116 and incident toward the first red pixel electrode 114ra. The thickness T1-2 of the second red pixel electrode 114rb may be thinner than the thickness of the second layer L2 and thicker than the thickness of the first layer L1 (or the third layer L3). As described above, since the second red pixel electrode 114rb includes fluorine, even if it is formed thicker than the first layer L1 (or the third layer L3), the reduction in light transmittance can be reduced or minimized.

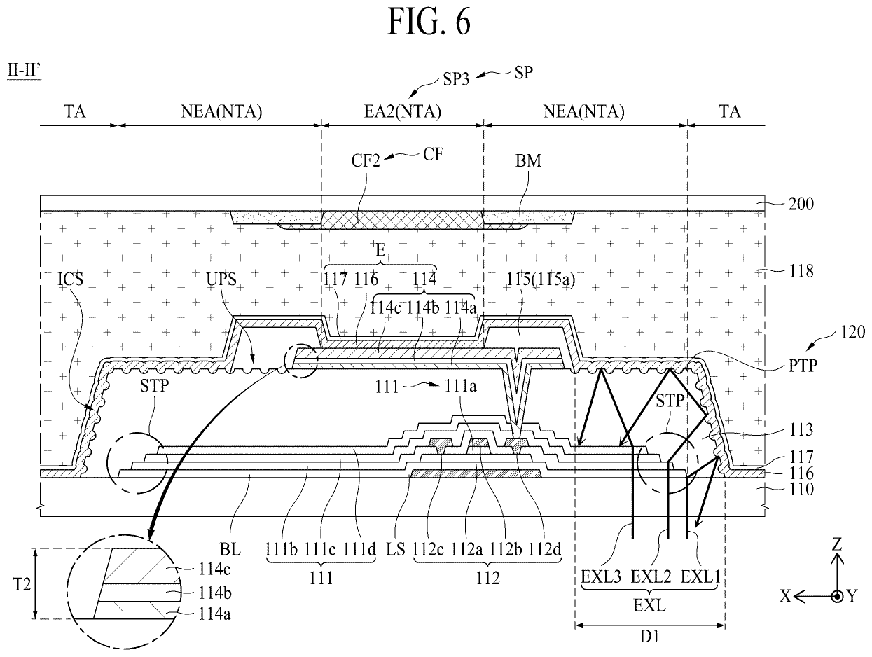

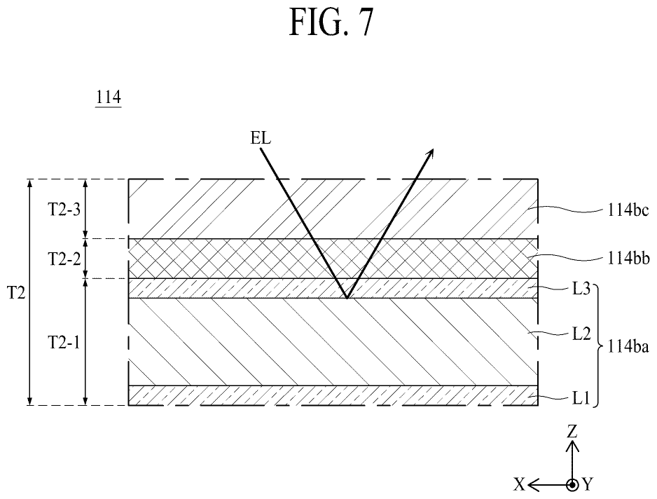

FIG. 6 is a schematic cross-sectional view of the line II-II′ shown in FIG. 2, and FIG. 7 is a cross-sectional view showing one example of a pixel electrode illustrated in FIG. 6. FIG. 6 shows a cross-sectional view of the blue subpixel SP3, and FIG. 7 shows a cross-sectional view of the pixel electrode 114 included in the blue subpixel SP3. The blue subpixel SP3 is identical to the red subpixel SP4 described above, except that the structure of the pixel electrode 114 and the color filter are changed to a blue color filter CF2. Therefore, the same drawing symbols have been assigned to the same configuration, and only the different configurations will be described hereinafter.

In the transparent display apparatus 100 according to one embodiment of the present disclosure, the pixel electrode 114 including the blue subpixel SP3 may be provided as follows.

For example, as shown in FIG. 7, the pixel electrode 114 of the blue subpixel SP3 may include a first blue pixel electrode 114ba, a second blue pixel electrode 114bb, and a third blue pixel electrode 114bc. The second blue pixel electrode 114bb may be placed on the first blue pixel electrode 114ba. The third blue pixel electrode 114bc may be placed on the second blue pixel electrode 114bb. The first blue pixel electrode 114ba according to one example may include a first layer L1, a second layer L2, and a third layer L3 that are sequentially stacked. The first layer L1 may be ITO. The second layer L2 may be Ag. The third layer L3 may be ITO. However, it is not limited thereto, and if it has a work function capable of emitting light from the organic light-emitting layer 116 and can reflect light emitted from the organic light-emitting layer 116 toward the opposing substrate 200, the first layer L1, the second layer L2, and the third layer L3 can each be formed of different materials.

The second blue pixel electrode 114bb may be disposed on the third layer L3. The third blue pixel electrode 114bc may be disposed on the second blue pixel electrode 114bb. The third blue pixel electrode 114bc and the second blue pixel electrode 114bb are for matching the resonance distance of the micro cavity to improve the light extraction efficiency of the blue subpixel SP3.

Therefore, in the transparent display apparatus 100 according to one embodiment of the present disclosure, the third blue pixel electrode 114bc and the second blue pixel electrode 114bb are disposed on the first blue pixel electrode 114ba, so that a resonance distance for implementing micro-cavity characteristics can be implemented, and thus the light extraction efficiency of the blue sub-pixel SP3 can be improved.

Meanwhile, in the transparent display apparatus 100 according to one embodiment of the present disclosure, the pixel electrode 114 included in the blue subpixel SP3 may include fluorine (F). For example, the second blue pixel electrode 114bb of the pixel electrode 114 included in the blue subpixel SP3 may include fluorine (F). Since the second blue pixel electrode 114bb is formed together with the second red pixel electrode 114rb, it may include fluorine.

Therefore, the transparent display apparatus 100 according to one embodiment of the present disclosure may have a feature in which the second blue pixel electrode 114bb among the pixel electrodes 114 arranged in the blue subpixel SP3 is formed of FTO. When the second blue pixel electrode 114bb is formed of FTO, the transmittance of light emitted from the organic light-emitting layer 116 and reflected on the second layer L2 may be improved.

If the light transmittance of the second blue pixel electrode 114bb including fluorine (F) is high, as shown in FIG. 7, the transmittance of the light EL (or the light EL emitted from the organic light-emitting layer 116) of the organic light-emitting layer 116 reflected by the second layer L2 passing through the second blue pixel electrode 114bb can be high, and thus the light extraction efficiency of the blue subpixel SP3 can be improved.

Therefore, the transparent display apparatus 100 according to one embodiment of the present disclosure is provided such that the pixel electrode 114 (or the second blue pixel electrode 114bb included in the blue subpixel SP3) includes fluorine (F), thereby satisfying the microcavity resonance distance of the blue subpixel SP3, and since the light transmittance can be improved, the light extraction efficiency of the blue subpixel SP3 can be improved.

As a result, in the transparent display apparatus 100 according to one embodiment of the present disclosure, since the pixel electrode 114 is disposed on the planarization layer 113 before the ashing process forming the light path changing portion 120, the pixel electrode 114 can be provided flatly, so that the reflectivity can be improved compared to the pixel electrode having the uneven structure, and thus the light extraction efficiency can be improved.

In addition, the transparent display apparatus 100 according to one embodiment of the present disclosure is provided such that the pixel electrode 114 included in at least one of the plurality of subpixels includes fluorine, so that the transmittance of the pixel electrode 114 can be improved, and thus the light efficiency of the light emission area can be further improved. For example, since the pixel electrode 114 included in each of the red subpixel SP4 and the blue subpixel SP3 is provided to include fluorine (F), the light transmittance of each of the red subpixel SP4 and the blue subpixel SP3 can be improved, and thus the overall light extraction efficiency can be improved.

Meanwhile, since the transparent display apparatus 100 according to one embodiment of the present disclosure is provided such that at least one subpixel among the plurality of subpixels includes the pixel electrode 114 containing fluorine, the light extraction efficiency can be improved, and thus, compared to a general transparent display apparatus in which the pixel electrode 114 does not include fluorine, the light emission efficiency can be improved to the same or higher even with low power, so that the overall power consumption can be reduced.

In addition, the transparent display apparatus 100 according to one embodiment of the present disclosure is provided such that the pixel electrodes 114 included in each of the red subpixel SP4 and the blue subpixel SP3 satisfy the micro cavity resonance distance, thereby maximizing the improvement in light extraction efficiency.

Referring again to FIG. 7, the pixel electrode 114 included in the blue subpixel SP3 may be provided with a second thickness T2. Since the pixel electrode 114 of the blue subpixel SP3 further includes a third blue pixel electrode 114bc. Therefore, the pixel electrode 114 of the blue subpixel SP3 may be provided thicker than the pixel electrode 114 of the red subpixel SP4. Accordingly, the second thickness T2 may be thicker than the first thickness T1.

The blue subpixel SP3 requires a longer resonance distance than the red subpixel SP4 to have microcavity characteristics. Accordingly, the transparent display apparatus 100 according to one embodiment of the present disclosure may have a structural feature in which the thickness T1 of the pixel electrode 114 included in the red subpixel SP4 is thinner than the thickness T2 of the pixel electrode 114 included in the blue subpixel SP3.

As shown in FIG. 7, the second thickness T2 of the pixel electrode 114 included in the blue subpixel SP3 may be a sum of a thickness T2-1 of the first blue pixel electrode 114ba, a thickness T2-2 of the second blue pixel electrode 114bb, and a thickness T2-3 of the third blue pixel electrode 114bc.

The thickness T2-1 of the first blue pixel electrode 114ba may be a sum of a thickness of each of the first layer L1, the second layer L2, and the third layer L3. Here, the thickness of the second layer L2 may be thicker than the thickness of the first layer L1 (or the third layer L3). This is because the second layer L2 must reflect light emitted from the organic light-emitting layer 116 and incident toward the first blue pixel electrode 114ba.

The thickness T2-2 of the second blue pixel electrode 114bb may be thinner than the thickness of the second layer L2 and thicker than the thickness of the first layer L1 (or the third layer L3). As described above, since the second blue pixel electrode 114bb includes fluorine, even if it is thicker than the first layer L1 (or the third layer L3), the reduction in light transmittance can be reduced or minimized.

The third blue pixel electrode 114bc is intended to match the resonance distance of the blue subpixel SP3 and may be formed thicker than the second blue pixel electrode 114bb. Accordingly, the thickness T2-3 of the third blue pixel electrode 114bc may be thicker than the thickness T2-2 of the second blue pixel electrode 114bb.

Therefore, the transparent display apparatus 100 according to one embodiment of the present disclosure may have a structural feature in which the first red pixel electrode 114ra is provided with the same thickness as the first blue pixel electrode 114ba, and the second red pixel electrode 114rb is provided with the same thickness as the second blue pixel electrode 114bb. And, the transparent display apparatus 100 according to one embodiment of the present disclosure may have a structural feature in which the thickness T2-3 of the third blue pixel electrode 114bc is thicker than the thickness T2-2 of the second blue pixel electrode 114bb. For example, the thickness T2-3 of the third blue pixel electrode 114bc may be 500 Å to 600 Å.

Meanwhile, in the transparent display apparatus 100 according to one embodiment of the present disclosure, the third blue pixel electrode 114bc may be formed of a different material from the second blue pixel electrode 114bb. For example, the third blue pixel electrode 114bc may be formed of IZO, and the second blue pixel electrode 114bb may be formed of FTO.

If the third blue pixel electrode 114bc having a thickness of 500 Å to 600 Å is made of ITO, the resonance distance of the blue subpixel SP3 can be satisfied, but since the ITO is thick and is polyized (or hardened), etching (or patterning) may be difficult. In contrast, if the third blue pixel electrode 114bc is formed of IZO, etching (or patterning) can be easily performed because the third blue pixel electrode 114bc is not polyized (or hardened) even if it is formed to have a thickness of 500 Å to 600 Å. Therefore, the transparent display apparatus 100 according to one embodiment of the present disclosure can be easily etched (or patterned) while satisfying the resonance distance of the blue subpixel SP3 by having the third blue pixel electrode 114bc made of a different material (e.g., IZO) than the second blue pixel electrode 114bb.

FIG. 8 is a schematic cross-sectional view of the line III-III′ shown in FIG. 2.

FIG. 8 shows a cross-sectional view in the first direction (Y-axis direction) of the second light emission area EA2 included in the white subpixel SP2. The white subpixel SP2 is identical to the red subpixel SP4 described above, except that the structure of the pixel electrode 114 and the color filter are deleted. Therefore, the same drawing symbols have been assigned to the same configuration, and only the different configurations will be described hereinafter.

In a transparent display apparatus 100 according to one embodiment of the present disclosure, the pixel electrode 114 including the white subpixel SP2 may be provided as follows.

For example, as shown in FIG. 8, the pixel electrode 114 of the white subpixel SP2 may be equipped only with the first white pixel electrode 114wa. This is to match the resonance distance of the white subpixel SP2. Accordingly, the transparent display apparatus 100 according to one embodiment of the present disclosure may have a structural feature in which the thickness T3 of the pixel electrode 114 included in the white subpixel SP2 is thinner than the thickness T1 of the pixel electrode 114 included in the red subpixel SP4.

Although not shown, the first white pixel electrode 114wa according to one example may include a first layer L1, a second layer L2, and a third layer L3 that are sequentially stacked. The first layer L1 may be ITO. The second layer L2 may be Ag. The third layer L3 may be ITO. However, it is not limited thereto, and if it has a work function capable of emitting light from the organic light-emitting layer 116 and can reflect light emitted from the organic light-emitting layer 116 toward the opposing substrate 200, the first layer L1, the second layer L2, and the third layer L3 can each be formed of different materials.

Meanwhile, the first white pixel electrode 114wa may be formed together with the first red pixel electrode 114ra and the first blue pixel electrode 114ba through the same process. Accordingly, the pixel electrode 114 of the white subpixel SP2 may not include fluorine. Therefore, the transparent display apparatus 100 according to one embodiment of the present disclosure may be provided such that the transmittance of the pixel electrode 114 included in each of the red subpixel SP4 and the blue subpixel SP3 is higher than the transmittance of the pixel electrode 114 included in the white subpixel SP2.

Meanwhile, the transparent display apparatus 100 according to one embodiment of the present disclosure may be provided with an organic light-emitting layer 116 provided as a common layer to have a WTE reverse structure in which a red light-emitting layer, a yellow-green light-emitting layer, and a green light-emitting layer are sequentially laminated in an upward direction. However, under a condition of the organic light-emitting layer 116 having a WTE reverse structure, the micro-cavity resonance distance of the red sub-pixel SP4 and the blue sub-pixel SP3 can be satisfied by adjusting the thickness of the pixel electrode 114, but the micro-cavity resonance distance of the green sub-pixel SP1 cannot be satisfied.

In order to satisfy the micro-cavity resonance distance of the green sub-pixel SP1, the WTE inverse structure of the organic light-emitting layer 116 must be changed to a structure in which the upper and lower sides are inverted. In this case, the micro-cavity resonance distances of the red sub-pixel SP4 and the blue sub-pixel SP3 cannot be satisfied.

Therefore, the transparent display apparatus 100 according to one embodiment of the present disclosure may have a structural feature in which only the pixel electrodes 114 of the white subpixel SP2, the blue subpixel SP3, and the red subpixel SP4 have different thicknesses.

Although not shown, the pixel electrode of the green subpixel SP1 may be formed together with the first red pixel electrode 114ra and the first blue pixel electrode 114ba through the same process. Accordingly, the pixel electrode 114 of the green subpixel SP1 may include a first layer L1, a second layer L2, and a third layer L3 that are sequentially stacked, and may not include fluorine. For example, the first layer L1 may be ITO, the second layer L2 may be Ag, and the third layer L3 may be ITO. However, it is not limited thereto, and if it has a work function capable of emitting light from the organic light-emitting layer 116 and can reflect light emitted from the organic light-emitting layer 116 toward the opposing substrate 200, the first layer L1, the second layer L2, and the third layer L3 of the green subpixel SP1 may each be formed of different materials.

As a result, the transparent display apparatus 100 according to one embodiment of the present disclosure may be provided such that only the pixel electrodes 114 of the blue subpixel SP3 and the red subpixel SP4 may include fluorine, and the pixel electrodes 114 of the green subpixel SP1 and the white subpixel SP2 may not include fluorine.

However, it is not limited thereto, and when an uppermost layer of the pixel electrode 114 included in each of the white subpixel SP2 and the green subpixel SP1 is made of ITO, the uppermost layer of the pixel electrode 114 included in each of the white subpixel SP2 and the green subpixel SP1 can also be converted to FTO including fluorine by an ashing process using a fluorine process gas. In this case, the transparent display apparatus 100 according to one embodiment of the present disclosure is provided such that each of the pixel electrodes 114 of the green subpixel SP1, the white subpixel SP2, the blue subpixel SP3, and the red subpixel SP4 includes fluorine (F), so that the overall light extraction efficiency can be improved due to the improvement in light transmittance in each of the green subpixel SP1, the white subpixel SP2, the blue subpixel SP3, and the red subpixel SP4.

Meanwhile, the transparent display apparatus 100 according to one embodiment of the present disclosure may have a structural feature in which the pixel electrode 114 of the green subpixel SP1 is provided with the same thickness as the pixel electrode 114 of the white subpixel SP2, and the pixel electrodes 114 of the white subpixel SP2, the blue subpixel SP3, and the red subpixel SP4 have different thicknesses, because the micro-cavity resonance distance of the green subpixel SP1 cannot be satisfied due to the WTE inverse structure.

Referring to FIG. 2, in the transparent display apparatus 100 according to one embodiment of the present disclosure, a width W2 of a second light emission area EA2 of a white sub-pixel SP2 in the first direction (Y-axis direction) may be provided to be narrower than a width W1 of the first light emission area EA1 of the white sub-pixel SP2 in the first direction (Y-axis direction) on a plane.

Specifically, as shown in FIG. 2, the first light emission area EA1 of the white subpixel SP2 can be placed between the green subpixel SP1 and the blue subpixel SP3 in the first direction (Y-axis direction). The second light emission area EA2 of the white subpixel SP2 can be arranged spaced apart from the first light emission area EA1 in the second direction (X-axis direction). For example, the second light emission area EA2 of the white subpixel SP2 can be arranged to cross the transmissive area TA. The second light emission area EA2 of the white subpixel SP2 may be provided in a form that has a narrower width than the first light emission area EA1 in the first direction (Y-axis direction) and is longer than the first light emission area EA1 in the second direction (X-axis direction). Accordingly, the second light emission area EA2 of the white subpixel SP2 can have a same area or a similar area as the first light emission area EA1, and thus can have a same or a similar light efficiency as the first light emission area EA1.

Meanwhile, the reason why the width W2 of the second light emission area EA2 of the white subpixel SP2 in the first direction (Y-axis direction) is provided narrower than the width W1 of the first light emission area EA1 of the white subpixel SP2 in the first direction (Y-axis direction) on the plane is to minimize an area (or an area overlapping with the transmissive area TA) where the second light emission area EA2 of the white subpixel SP2 covers the transmissive area TA, thereby reducing or minimizing the decrease in the transmittance of the transmissive area TA.

Therefore, in the transparent display apparatus 100 according to one embodiment of the present disclosure, the width W2 of the second light emission area EA2 of the white subpixel SP2 in the first direction (Y-axis direction) is provided to be narrower than the width W1 of the first light emission area EA1 of the white subpixel SP2 in the first direction (Y-axis direction) on a plane, so that the reduction in the transmittance of the transmissive area TA can be reduced or minimized.

Referring to FIG. 3 and FIG. 8, in the transparent display apparatus 100 according to one embodiment of the present disclosure, the bank 115 may include a first bank 115a adjacent to the second light emission area EA2 of one of the plurality of colored sub-pixels (e.g., the red sub-pixel SP4), and a second bank 115b adjacent to the second light emission area EA2 of the white sub-pixel SP2.

As described above, the width W2 of the second light emission area EA2 of the white subpixel SP2 in the first direction (Y-axis direction) may be provided to be narrower than the width W1 of the first light emission area EA1 in the first direction (Y-axis direction). However, if the width of the first direction (Y-axis direction) of the planarization layer 113 overlapping the second light emission area EA2 of the white subpixel SP2 is narrow, there is a problem that when applying a chemical solution to form the bank 115 on the planarization layer 113, the chemical solution flows down to the transmissive area and the bank is lost. If the bank is lost, a dark spot defect may occur.

Therefore, the transparent display apparatus 100 according to one embodiment of the present disclosure may be provided such that the second distance D2 (shown in FIG. 8) from an end of the second bank 115b to an end of the planarization layer 113 adjacent to the transmissive area TA is longer than the first distance D1 (shown in FIG. 3) from an end of the first bank 115a to an end of the planarization layer 113 adjacent to the transmissive area TA. That is, in the transparent display apparatus 100 according to one embodiment of the present disclosure, a planarization layer 113 may be formed to extend further from the second light emission area EA2 of the white subpixel SP2 toward the transmissive area TA than from the colored subpixel so as to cover the inorganic films 111 adjacent to the transmissive area TA. Accordingly, the transparent display apparatus 100 according to one embodiment of the present disclosure can prevent loss of the second bank 115b positioned adjacent to the second light emission area EA2 of the white subpixel SP2, thereby improving dark spot defects, and thus improving the yield and/or reliability of the transparent display apparatus.

Meanwhile, as shown in FIG. 2, the transparent display apparatus 100 according to one embodiment of the present disclosure may have the first light emission area EA1 including the plurality of colored sub-pixels and the white sub-pixel respectively, and the first light emission area EA1 may be electrically connected to the second light emission area EA2 through a repair line RPL.

For example, the repair line RPL may be electrically connected to each of a thin film transistor 112 provided in the red subpixel SP4, the pixel electrode 114 provided in the first light emission area EA1, and the pixel electrode 114 provided in the second light emission area EA2. Repair line RPL is to cut off power to the light emission area where a dark spot occurs when a dark spot defect occurs in one of the two light emission areas, and to operate a remaining light emission area normally. For example, when a dark spot defect occurs in the first light emission area EA1, the repair line RPL connected to the pixel electrode 114 of the first light emission area EA1 is cut by a cutting apparatus such as a laser, so that the power applied to the first light emission area EA1 is cut off and the first light emission area EA1 does not operate, and only the second light emission area EA2 can operate normally.

Therefore, in the transparent display apparatus 100 according to one embodiment of the present disclosure, even if a dark spot defect occurs in one of the two light emission areas included in one subpixel SP, the remaining light emission area can be driven normally through the repair line RPL, so that the entire subpixel SP in which the dark spot occurs can be prevented from not being driven. In one example, the repair line RPL may be placed partially in the transmissive area TA.

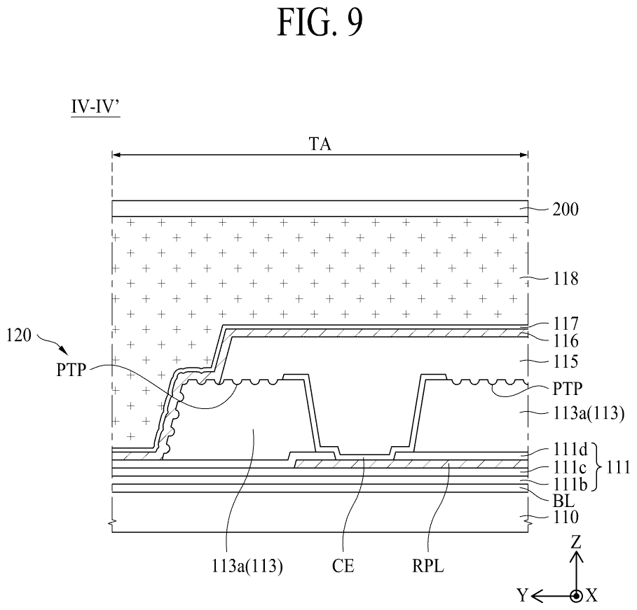

FIG. 9 is a schematic cross-sectional view of the line IV-IV′ shown in FIG. 2.

Referring to FIG. 9, the transparent display apparatus 100 according to one embodiment of the present disclosure may further include a connecting electrode CE.

According to one example, the connecting electrode CE may be connected to each of the pixel electrode 114 and the repair line RPL provided in the first light emission area EA1. As described above, the repair line RPL may be electrically connected to the pixel electrode 114 of the first light emission area EA1. For example, the repair line RPL can be electrically connected to the pixel electrode 114 of the first light emission area EA1 through the connecting electrode CE. The connecting electrode CE is arranged on the same layer as the pixel electrode 114 provided in the first light emission area EA, so that it can be connected to the pixel electrode 114 of the first light emission area EA. And, the connecting electrode CE can be connected to the repair line RPL through a contact hole provided in the planarization layer 113 (or a dummy planarization layer 113a). Accordingly, the connecting electrode CE can apply the driving voltage applied from the thin film transistor to the pixel electrode 114 of the first light emission area EA1. As shown in FIG. 9, the connecting electrode CE can be placed on the planarization layer 113 (or the dummy planarization layer 113a).

Meanwhile, the planarization layer 113 may include a dummy planarization layer 113a partially disposed between the repair line RPL and the connecting electrode CE. Since the connecting electrode CE is formed on the same layer as the pixel electrode 114, as shown in FIG. 9, the dummy planarization layer 113a may be partially disposed between the repair line RPL and the connecting electrode CE.

The connecting electrode CE can be formed through the same process on the same layer as the pixel electrode 114. Therefore, after the connecting electrode CE is formed on the dummy planarization layer 113a, an ashing process for forming the light path change portion 120 can be performed. Therefore, the transparent display apparatus 100 according to one embodiment of the present disclosure may have a structural feature in which the light path changing portion 120 (or the plurality of pattern portions PTP) is provided on an upper surface of the dummy planarization layer 113a that is not covered by the connecting electrode CE among the upper surfaces of the dummy planarization layer 113a, and also on a side surfaces of the dummy planarization layer 113a. Due to this, light incident on the substrate 110 may have its light path changed by the light path changing portion 120 (or the plurality of pattern portions PTP) provided in the dummy planarization layer 113a and may be emitted toward the substrate 110 or may be extinguished within the substrate 110.

The transparent display apparatus 100 according to one embodiment of the present disclosure may have a structural feature in which each of an organic light-emitting layer 116 and the opposing electrode 117 formed after the bank 115 is formed along the profile of the light path changing portion 120 (or the plurality of pattern portions PTP) provided on each of the side surface of the dummy planarization layer 113a and the upper surface of the dummy planarization layer 113a that is not covered by the bank 115.

For example, as shown in FIG. 9, the organic light-emitting layer 116 and the opposing electrode 117 can be formed to have a rough structure along the profile of the light path changing portion 120 (or the plurality of pattern portions PTP) provided on the upper surface of the dummy planarization layer 113a that is not covered by the bank 115. In addition, the organic light-emitting layer 116 and the opposing electrode 117 can be formed to have a rough structure along the profile of the light path changing portion 120 (or the plurality of pattern portions PTP) provided on the side surface of the dummy planarization layer 113a.

As a result, the transparent display apparatus 100 according to one embodiment of the present disclosure may be formed such that the planarization layer 113 is extended to cover the step STP of inorganic films 111 adjacent to the transmissive area TA, and the extended planarization layer 113 may be provided to have the light path changing portion 120 (or the plurality of pattern portions PTP). Therefore, the transparent display apparatus 100 according to one embodiment of the present disclosure can prevent diffraction of light (or light incident on the substrate 110 adjacent to the transmissive area TA) passing through the transmissive area TA, so that the clarity of an object or an image shown to a user through the transmissive area TA can be improved.

According to one embodiment, a transparent display apparatus includes a substrate having a transmissive area TA and a non-transmissive area NTA adjacent to the transmissive area TA. A thin film transistor (TFT) is formed in the non-transmissive area NTA, and a plurality of inorganic films 111 (such as insulating layers, interlayer dielectrics, or passivation films) are stacked on the thin film transistor. A planarization layer 113 is formed over the inorganic films 111 and the thin film transistor 112. The planarization layer 113 includes an upper surface UPS and an inclined side surface ICS extending from the upper surface UPS toward the transmissive area TA. A light path changing patterned structure 120 is formed on at least one of the upper surface or the inclined side surface of the planarization layer 113. The patterned structure 120 may include a plurality of protrusions or recesses, which may be arranged in a regular (e.g., periodic) or irregular pattern.

In some examples, the planarization layer 113 extends from the non-transmissive area NTA into the transmissive area TA, such that the inclined side surface ICS and the patterned structure 120 formed thereon partially overlap with the transmissive area TA in plan view. A light emitting element E may be disposed on a region of the planarization layer 113 in the non-transmissive area NTA and may be arranged such that it does not overlap with the patterned structure 120 in plan view. In addition, a bank 115 may be formed adjacent to the light emitting element E and may be positioned such that it partially overlaps with the patterned structure 120 from a plan view.

Embodiments of the present disclosure have been described in more detail with reference to the accompanying drawings, but the present disclosure is not necessarily limited to these embodiments and can be practiced in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of this disclosure shall be construed by the claims, and all technical ideas within the scope of the claims shall be construed to be included within the scope of the claims.

The present disclosure provides the planarization layer formed to cover the inorganic films adjacent to the transmissive area, and the planarization layer is provided with the light path changing portion (or the plurality of pattern portions), so that diffraction of light (or light incident on the substrate adjacent to the transmissive area) passing through the transmissive area can be prevented, thereby improving a clarity of an object or an image shown to a user through the transmissive area.

The present disclosure provides that the pixel electrode of at least one subpixel among the plurality of subpixels includes a fluorine, so that the transmittance of the pixel electrode can be improved, and thus the light efficiency of the light emission area can be improved.

Since the present disclosure is provided with the pixel electrode including a fluorine so that a light extraction efficiency can be improved, the pixel electrode can have the same luminous efficiency or improve luminous efficiency more than that of a transparent display apparatus in which the pixel electrode does not include the fluorine even with low power, so that the overall power consumption can be reduced.

The present disclosure can improve dark spot defects by preventing bank loss by forming the planarization layer that extends toward the transmissive area to cover the inorganic films adjacent to the transmissive area.

The effects that can be obtained from the present disclosure are not limited to those mentioned above, and other effects not mentioned will be apparent to one having ordinary skill in the art from the following description.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transparent display apparatus comprising:
a substrate including a display area, each of which is provided with a transmissive area and a non-transmissive area adjacent to the transmissive area and having a plurality of subpixels arranged therein;
a plurality of inorganic films provided in the non-transmissive area;
a step formed by the plurality of inorganic films;
a planarization layer on the plurality of inorganic films; and
a light path changing patterned structure partially included in the planarization layer.

2. The transparent display apparatus of claim 1, wherein the light path changing patterned structure is provided on each of an upper surface and an inclined surface of the planarization layer adjacent to the transmissive area.

3. The transparent display apparatus of claim 1, wherein the light path changing patterned structure includes a plurality of pattern portions, and the plurality of pattern portions are regular or irregular.

4. The transparent display apparatus of claim 3, wherein the plurality of pattern portions changes a light path of at least a portion of external light incident through the substrate or the plurality of inorganic films in a direction toward the substrate.

5. The transparent display apparatus of claim 1, wherein each of the plurality of subpixels includes a pixel electrode partially arranged on an upper surface of the planarization layer, and the upper surface of the planarization layer on which the pixel electrode is arranged is provided flat.

6. The transparent display apparatus of claim 5,
wherein each of the plurality of subpixels further includes a bank covering an edge of the pixel electrode, and the bank partially covers the light path changing patterned structure.

7. The transparent display apparatus of claim 6,
wherein the plurality of subpixels include a plurality of colored subpixels and a white subpixel arranged adjacent to at least some of the plurality of colored subpixels,
wherein the plurality of colored subpixels include a green subpixel, a blue subpixel, and a red subpixel arranged in a column in a first direction, and
wherein the white subpixel is arranged to protrude in a second direction different from the first direction between the green subpixel and the blue subpixel.

8. The transparent display apparatus of claim 7, wherein the pixel electrodes included in each of the red subpixel and the blue subpixel include fluorine.

9. The transparent display apparatus of claim 8, wherein a transmittance of the pixel electrode included in each of the red subpixel and the blue subpixel is higher than a transmittance of the pixel electrode included in the white subpixel.

10. The transparent display apparatus of claim 7, wherein a thickness of the pixel electrode included in the red subpixel is thinner than a thickness of the pixel electrode included in the blue subpixel.

11. The transparent display apparatus of claim 7, wherein a thickness of the pixel electrode included in the white subpixel is thinner than a thickness of the pixel electrode included in the red subpixel.

12. The transparent display apparatus of claim 7,
wherein the pixel electrode of the red subpixel includes a first red pixel electrode and a second red pixel electrode on the first red pixel electrode,
wherein the pixel electrode of the blue subpixel includes a first blue pixel electrode, a second blue pixel electrode on the first blue pixel electrode, and a third blue pixel electrode on the second blue pixel electrode,
wherein the first red pixel electrode is provided with a same thickness as the first blue pixel electrode, and
wherein the second red pixel electrode is provided with a same thickness as the second blue pixel electrode.

13. The transparent display apparatus of claim 12, wherein the third blue pixel electrode is made of a different material from the second blue pixel electrode.

14. The transparent display apparatus of claim 12, wherein a thickness of the third blue pixel electrode is thicker than a thickness of the second blue pixel electrode.

15. The transparent display apparatus of claim 7,
wherein each of the plurality of colored subpixels and the white subpixel includes a first light emission area and a second light emission area that are arranged spaced apart from each other, and
wherein a width of the second light emission area of the white subpixel in the first direction is narrower than a width of the first light emission area of the white subpixel in the first direction on a plane.

16. The transparent display apparatus of claim 15,
wherein the bank includes a first bank adjacent to the second light emission area of one of the plurality of color sub-pixels, and a second bank adjacent to the second light emission area of the white sub-pixel, and
wherein a second distance from an end of the second bank to an end of the planarization layer adjacent to the transmissive area is longer than a first distance from an end of the first bank to an end of the planarization layer adjacent to the transmissive area.

17. The transparent display apparatus of claim 7,
wherein each of the plurality of colored subpixels and the white subpixel includes a first light emission area and a second light emission area that are arranged spaced apart from each other, and
wherein the first light emission area is electrically connected to the second light emission area through a repair line.

18. The transparent display apparatus of claim 17, further comprising:
a connecting electrode connected to each of the pixel electrode and the repair line provided in the first light emission area, and
wherein the connecting electrode is arranged on a same layer as the pixel electrode provided in the first light emission area.

19. The transparent display apparatus of claim 18,
wherein the planarization layer includes a dummy planarization layer, a portion of which is disposed between the repair line and the connecting electrode, and
wherein the light path changing patterned structure is provided on an upper surface of the dummy planarization layer, which is not covered by the connecting electrode, and on a side surface of the dummy planarization layer.

20. The transparent display apparatus of claim 19,
wherein each of the plurality of subpixels further comprises:
an organic light-emitting layer disposed on the pixel electrode and the bank; and
an opposing electrode disposed on the organic light-emitting layer, and
wherein each of the organic light-emitting layer and the opposing electrode is formed along a profile of the light path changing patterned structure provided on each of the side surface of the dummy planarization layer and the upper surface of the dummy planarization layer not covered by the bank.

21. A transparent display apparatus comprising:
a substrate having thereon a transmissive area and a non-transmissive area adjacent to the transmissive area;
a thin film transistor in the non-transmissive area;
a plurality of inorganic films on the thin film transistor;
a planarization layer on the plurality of inorganic films and the thin film transistor, the planarization layer having an upper surface and an inclined side surface extending from the upper surface; and
a light path changing patterned structure at least on one of the upper surface and the inclined side surface of the planarization layer.

22. The transparent display apparatus of claim 21, wherein the light path changing patterned structure, in operation, is configured to redirect light incident on or emitted through the transmissive area.

23. The transparent display apparatus of claim 21, wherein the planarization layer extends from the non-transmissive area into the transmissive area, and
wherein the light path changing patterned structure at the inclined side surface of the planarization layer overlaps with the transmissive area from a plan view.

24. The transparent display apparatus of claim 21, wherein the light path changing patterned structure comprises a plurality of protrusions or recesses arranged in a regular or irregular pattern.

25. The transparent display apparatus of claim 21, further comprising a light emitting element on the planarization layer,
wherein the light emitting element does not overlap with the light path changing patterned structure from a plan view.

26. The transparent display apparatus of claim 25, further comprising a bank adjacent to the light emitting element,
wherein the bank partially overlaps with the light path changing patterned structure from a plan view.
